(19) United States
(12) Patent Application Publication
(10) Pub. No.: US 2010/0244585 A1
(43) Pub. Date: Sep. 30, 2010

(54) HIGH-TEMPERATURE CAPACITORS AND METHODS OF MAKING THE SAME

(75) Inventors: Daniel Qi Tan, Rexford, NY (US); Yang Cao, Niskayuna, NY (US); Patricia Chapman Irwin, Altamont, NY (US); Donald Cunningham, Dallas, TX (US)

Correspondence Address: GENERAL ELECTRIC COMPANY;GLOBAL RESEARCH, ONE RESEARCH CIRCLE, BLDG. K1-3A59, NISKAYUNA, NY, 12309, US

(73) Assignee: General Electric Company, Schenectady, NY (US)

(21) Appl. No.: 12/412,248

(22) Filed: Mar. 26, 2009

(51) Int. Cl. H01G 4/30; H02M 3/06; H05K 7/00

(52) U.S. Cl. 307/109; 361/301.4; 361/760; 29/25.42

(57) ABSTRACT

High-temperature, multiple-layer polymer (MLP) capacitors with a stacked electrode arrangement are disclosed. The capacitor electrodes are separated by a polymer dielectric that is stable at high temperatures. In some embodiments, the polymer dielectric also has a high permittivity and is filled with high-permittivity nanoparticles, which enables the capacitor to achieve a very high capacitance density.

### BACKGROUND OF THE INVENTION

The subject matter disclosed herein relates generally to electrical capacitors, and more particularly to the configuration of high-temperature polymer-film capacitors and the dielectric materials used in therein.

Discrete capacitors are used in many electronic applications, such as noise suppression, filtering, electrical decoupling, bypassing, termination, and frequency determination. Over the last decade, significant advances in capacitor reliability and performance have been achieved through a combination of advanced manufacturing techniques and new materials, particularly in the field of multiple-layer polymer capacitors (MLPs). Despite recent advances, however, current MLP technology may be insufficient in many high-performance, high-temperature applications. For example, efficient electronic packaging techniques such as package-on-package (POP) provide limited spacing for embedded capacitors. Furthermore, typical MLPs are too bulky to provide high enough capacitance in the small space available within the POP configuration. For another example, in high-frequency, high-voltage switching power converters, the capacitors used to control ripple current often experience high dissipation factors and low resonant frequency. The high dissipation factors result in lost efficiency and higher operating temperature, while the low resonant frequency results in reduced capacitance at higher frequencies.

Therefore, it may be advantageous to provide MLP capacitors with higher thermal stability and improved electrical properties compared to typical MLP capacitors.

### BRIEF DESCRIPTION OF THE INVENTION

In accordance with one aspect of the present invention, a stacked multi-layer capacitor is provided that includes a dielectric layer comprising polyetherimide or cyanoethyl cellulose.

In accordance another aspect of the present invention, a power converting system is provided that includes one or more stacked MLP capacitors. The dielectric layers of the MLP capacitors include polyetherimide and/or cyanoethyl cellulose.

In accordance another aspect of the present invention, a POP device with embedded MLP capacitors is provided. The MLP capacitors are configured to be disposed one or more the substrates of the POP device before the substrates are soldered together.

In accordance with other aspects of the present invention, methods are provided for making a stacked MLP capacitor that includes a dielectric layer comprising polyetherimide or cyanoethyl cellulose.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a diagram illustrating an embodiment of a POP device with improved MLP capacitors;

FIG. 2 is circuit diagram illustrating an embodiment of a power converting system with improved MLP capacitors;

FIG. 3 is a cross sectional view illustrating an embodiment of the improved MLP capacitors of FIGS. 1 and 2;

FIG. 4 is a perspective view illustrating an embodiments of the MLP capacitor shown in FIG. 3;

FIG. 5 is a flow chart illustrating an embodiment of a method of fabricating the MLP capacitor shown in FIGS. 3 and 4;

FIG. 6 is a partial perspective view of a system used in the method of FIG. 5;

FIG. 7 is a flow chart illustrating an embodiment of a method of fabricating the MLP capacitor shown in FIGS. 3 and 4 on a silicon wafer;

FIG. 8 is a flow chart illustrating an embodiment of a method of fabricating the MLP capacitor shown in FIGS. 3 and 4, using a reverse microgravure coating.

### DETAILED DESCRIPTION OF THE INVENTION

As discussed in detail below, embodiments of the present invention include a stacked MLP capacitor that is operable at high temperatures and exhibits improved electrical properties. Methods of manufacturing stacked MLP capacitors are also described. Some of the dielectric properties considered herein include dielectric constant, equivalent series resistance (ESR), equivalent series inductance (ESL). As used herein, dielectric constant is a ratio of the amount of electrical energy stored in the dielectric and the amount of electrical energy stored in a vacuum under an equivalent applied voltage. Equivalent series resistance (ESR) is the real, i.e. resistive, component of the complex impedance of a capacitor due to the resistivity of the metallic leads and electrodes and other non-ideal characteristics of the capacitor. Equivalent series inductance (ESL) is the inductive component of the complex impedance of a capacitor due to the inductive properties of the capacitor connections, and other non-ideal characteristics of the capacitor materials.

The MLP capacitors described herein include several layers of a metallized polymer film arranged such that the metal portions form electrodes separated by the polymer layers. The electrodes include a layer of a metal such as aluminum, copper, zinc or a combination thereof, and the polymer film acts as a dielectric that increases the capacitance of the MLP. In embodiments of the present invention, the polymer film includes a polymer or polymer composite that provides improved electrical and thermal characteristics over previous polymer types. In further embodiments, the MLP capacitor is fabricated in a stacked configuration that provides improved electrical characteristics, such as lower ESR and higher resonant frequency. The improved performance of the capacitor enables the capacitor to be used in applications wherein the capacitor will be subject to high voltage, high temperature, and high operating frequency such as in POP electronics and high-voltage, high-frequency power converters. Additionally, the high capacitance density provided by the polymer film enables the improved capacitor to provide a large capacitance within the small area available in POP electronics.

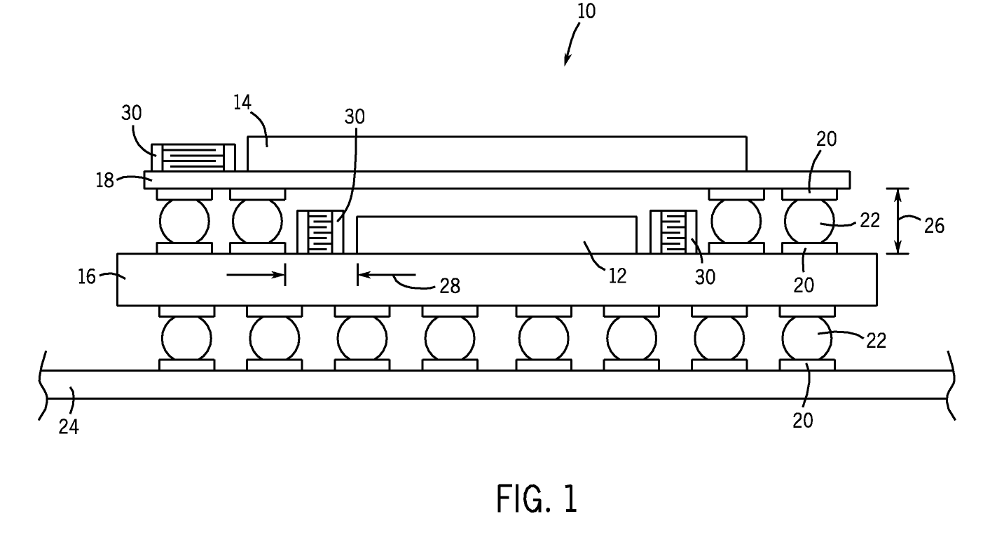

Turning now to the drawings, FIG. 1 is a diagrammatic illustration of a POP electronic device that employs one or more improved capacitors. The POP device 10 is an integrated circuit device that provides high density packaging of a wide range of electronics. In the embodiment shown, the device 10 may include a processor 12, such as an application-specific integrated circuit (ASIC), and a stacked memory 14, such as random access memory RAM, or flash memory. The processor 12 is mounted to a bottom substrate 16 that provides various electrical couplings between the processor 12 and the connection pads 20 on the top and bottom surface of the bottom substrate 16. An array of solder balls 22, electrically couples the bottom substrate 16 and, hence, the processor 12 to a mother board 24. The memory 14 is mounted to a top substrate 18 that provides various electrical couplings between the memory 14 and the connection pads 20 on the bottom surface of the top substrate 18. An array of solder balls 22, electrically couples the top substrate 18 and, hence, the memory 14 to the bottom substrate 16. In this way, the components of the POP device 10 may be compactly packaged, thereby providing a compact device and potentially increased processing speeds.

The compact packaging of the POP device 10, however, also reduces the amount of space available for additional components such as capacitors. In the embodiment shown, the space available for additional components may be limited by the vertical gap 26 between the bottom substrate 16 and top substrate 18, which may be approximately 300 microns or less. The space available for additional components may be further limited by the horizontal gap 28 between the edge of the processor 12 and the edge of the connection 20, which may be approximately five to seven millimeters or less. Furthermore, during the process of soldering the POP device, any devices installed in proximity to the solder balls 22 will experience high temperatures, which may reach approximately 260 degrees C. or higher.

Nevertheless, due to the techniques disclosed herein, the POP device 10 may include one or more MLP capacitors 30 disposed on the bottom substrate 16 or the top substrate 18. The MLP capacitors 30 shown in FIG. 1 may provide a wide range of functions such as suppressing electrical noise, suppressing current ripple, filtering, frequency determination, tuning, etc. In some embodiments, the MLP capacitors 30 may be decoupling capacitors that block noise from being communicated between the processor 12 and other components on the mother board 24. In embodiments, an internal MLP capacitor 30 may be located in the space bounded by the bottom substrate 16, the top substrate 18, the processor 12, and the connection pad 20 or solder ball 22. Additionally, an external MLP capacitor 30 may be located between the edge of the top substrate 18 and the memory 14. The area available for the external MLP capacitor 30 may be approximately twelve-by-twelve millimeters or less. To keep the overall height of the POP package low, the height of the external MLP capacitor 30 may be limited by the height of the memory 14, which may be approximately 300 microns in some embodiments. The MLP capacitors 30 may be soldered or wire bonded to the respective substrate. As will be described below, the improved MLP capacitors 30 may be fabricated with a polymer film that is stable under high temperatures and provides a high dielectric constant such that the desired capacitance is obtained within the small area provided on the POP device 10.

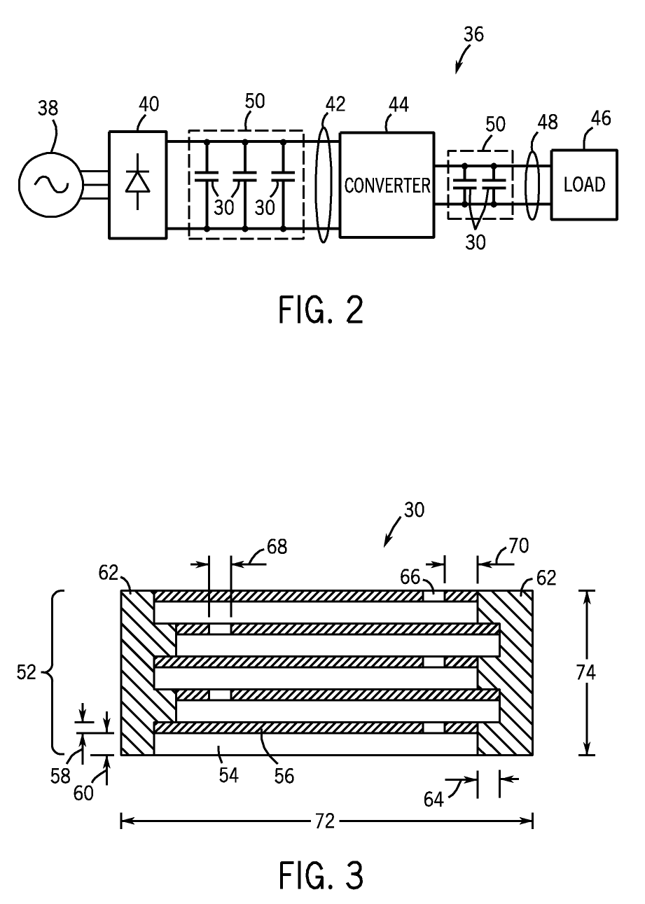

Another example of a device with improved MLP capacitors is shown in FIG. 2. FIG. 2 is a circuit diagram illustrating an embodiment of a power converting system 36 with improved MLP capacitors 30. The power converting system 36 may include a rectifier 40 coupled to an alternating current (AC) power source 38. The rectifier 40 performs full wave rectification of the three phase input voltage, outputting a direct current (DC) voltage to a DC bus 42. A converter 44 accepts the positive and negative lines of DC voltage from the DC bus 42 and uses pulse width modulation to generate an output DC voltage that is independent of the DC bus 42 voltage and powers the load 46. The converter 44 may be any type of DC-to-DC switch-mode power converter, such as buck, boost, buck-boost, SEPIC, flyback, push-pull, etc. The power converter 44 receives DC power from the input DC bus 42 and delivers DC power to a load 46 via the output DC bus 48.

It will be appreciated that the power converter shown is only one embodiment and that other embodiments may include any kind of switched-mode power supply. For example, in alternate embodiments, the power converting system 36 may also include an inverter for generating an alternating current (AC) output to power a load 46 such as a three-phase motor. Additionally, the power converting system 36 may be coupled to a DC power source such as a battery rather than the AC power source 38, and the rectifier 40 may, therefore, be eliminated.

Also included in the power converting system 36 are one or more capacitor banks 50 that control current and voltage ripple on the DC bus 42 and/or the output 48 of the converter 44. The capacitor banks 50 may include one or more improved MLP capacitors 30 arranged in parallel between the lines of the DC bus 42 and/or the converter output bus 48. In certain embodiments, the MLP capacitors 30 may be subject to voltages above approximately 1000 Volts and temperatures up to approximately 200 to 250 degrees C. Furthermore, both the rectifier 40 and the converter 44 will generate ripple currents with frequencies of up to 1 MHz. As will be described further below, the MLP capacitors may include a polymer film that is stable under high temperatures. Additionally, the MLP capacitors 30 may, in some embodiments, include a stacked configuration that reduces the ESR of the MLP capacitor 30, thereby reducing the capacitor's dissipation factor, which improves power efficiency and reduces heating. Furthermore, the stacked configuration also reduces the ESL of the MLP capacitor 30, thereby increasing the resonant frequency of the capacitor and enabling higher capacitance at high operating frequencies.

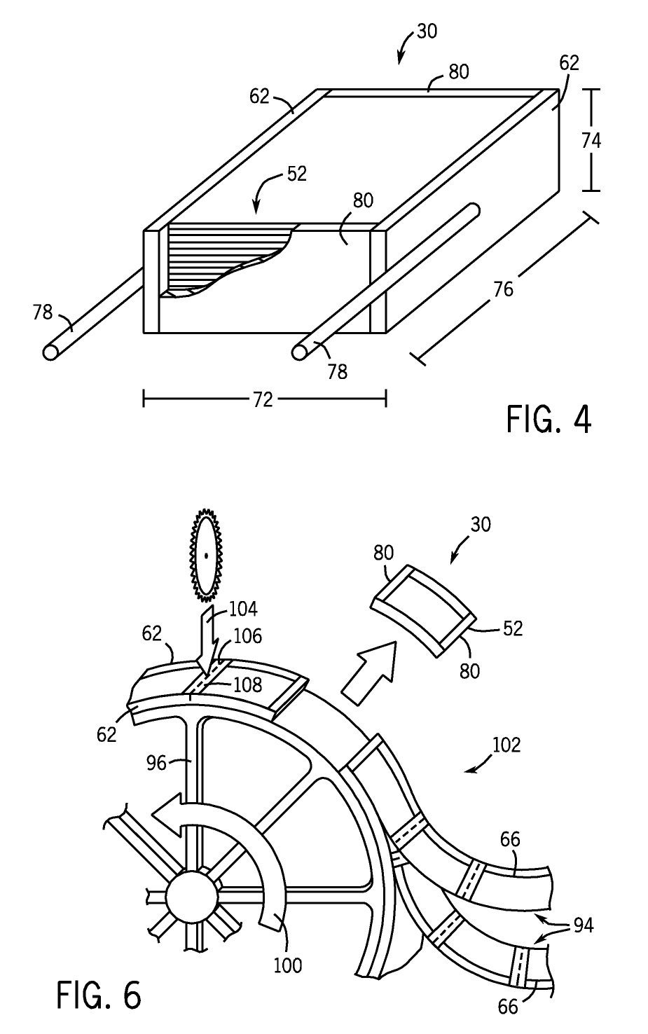

Turning now to FIGS. 3 and 4, various aspects of the MLP capacitors 30 are described. It will be appreciated that FIGS. 3 and 4 may not be drawn to scale. FIG. 3 is a cross sectional view, illustrating the MLP capacitors 30 of FIGS. 1 and 2, in accordance with aspects of the invention. The MLP capacitor 30 includes an electrode stack 52 that includes metal layers 56, which form the electrodes of the MLP capacitor 30, interleaved with polymer film layers 54. The metal layers 56 may include any type of metal such as aluminum, copper, silver, gold, etc., or alloys thereof, for example. In embodiments, the thickness 58 of the metal layers 56 may be approximately 50 to 300 Angstroms depending on the desired level of capacitance, and the metal layers 56 may include metal foil, or the metal layers 56 may be vapor deposited on the polymer layers 54. The thickness 60 of the polymer layers 54 (i.e. the separation distance between the electrodes) may be 0.6 to 3 microns or more, depending on the rated voltage of the capacitor 30. Depending on the level of capacitance desired, the number of layers in the electrode stack 52 may be as few as three (two electrodes and one polymer layer) up to several thousands of layers.

The sides of the electrode stack 32 may be terminated by lead terminations 62, which are electrically coupled to the metal layers 56 to enable the capacitor 50 to be coupled to a circuit. The lead terminations 62 may include metals such as aluminum, tin, copper, etc., and may be vapor deposited on the sides of the electrode stack 52. To provide a suitable connection between the lead terminations 62 and the electrodes, the metal layers 56 may be interleaved with a small overlap or offset 64, which alternates from side to side with each successive metal layer 56. In some embodiments, the offset 64 may measure approximately 3 millimeters. To ensure that each electrode makes contact with only one of the lead terminations 62, each metal layer 56 includes a narrow insulative gap 66 that runs along the margin of the metal layer 56 (into the page) and electrically insulates each electrode 56 from one of the lead terminations 62. The insulative gap 66 is an area of the metal layer 66 where the metal has been eliminated. For example, in some embodiments the insulative gap 66 is formed by vaporizing the metal with a laser. The width 68 of the insulative gap 66 may be approximately ten nanometers, and the distance 70 from the edge of the insulative gap 66 to the edge of the metal layer 62 may be approximately three to eight millimeters. The location of the insulative gap 66 alternates from left to right so that the metal layers 56 are alternatingly coupled to the left or right lead terminations 62.

For low power electronics, such a POP electronic devices, the overall width 70 of the MLP capacitor 30 may be approximately two to twelve millimeters or larger, and the height 72 may range from a few microns up to three-hundred microns. For high power electronics, such as the power converter of FIG. 2, the width 70 of the capacitor 50 may be up to several centimeters and the height 72 may be up to several centimeters.

Turning to FIG. 4, a perspective view of the MLP capacitor 30 of FIG. 3 is shown to illustrate additional features of the MLP capacitor 30, in accordance with embodiments. As shown in FIG. 4, the MLP capacitor 30 includes an electrode stack 52 with lead terminations 62 coupled to the sides of the electrode stack 52 such that half of the electrodes in the electrode stack are coupled to the left lead termination 62 and the other half are coupled to the right side lead termination 62, as described above. Coupled to the lead terminations 62 are conductors 78, which couple the MLP capacitor 30 to an electrical circuit. In some embodiments, the lead terminations 62, themselves, may be soldered directly to an external conductor such as a circuit board without the use of the wire bonds 78. Also shown in FIG. 4 are the insulated terminations 80 at the front and back sides of the electrode stack 52. The insulated terminations 80 prevent the electrodes from being short circuited by dirt and debris or other contaminants. The length 76 of the MLP capacitor 30 may be approximately 2 millimeters to several centimeters, depending on the desired level of capacitance and the amount of space available for the MLP capacitor 30. In some embodiments, such as where the capacitor 30 is disposed on the bottom substrate 16 of POP device 10, both the width 72 and the length 76 of the MLP capacitor 30 may be approximately 5 to 7 millimeters or less. In other embodiments, such as when the capacitor 30 is disposed on the top substrate 18 of the POP device 10, both the width 72 and the length 76 of the MLP capacitor 30 may be approximately 12 millimeters or less. In both embodiments, the height 74 of the MLP capacitor 30 may be approximately 300 microns or less. As will be described further below, the MLP capacitor 30 may, in some embodiments, be able to temporarily operate at temperatures of up to 300 degrees C. and provide approximately 40 to 50 nanofarads of capacitance per square millimeter.

As discussed above, the improved thermal and electrical properties of the capacitor 30 are achieved, in part, by the choice of material used in the polymer layer 34. In some embodiments, the polymer layer 34 may include polyetherimide (PEI), which is commercially available from SABIC Innovative Plastics under the tradenames Ultem® and Extem®. The polymer layer 34 may also include a PEI-Siloxane composite polymer, available from SABIC Innovative Plastics under the tradename Siltem®. The polymer layer 34 may also include cyanoethyl cellulose (CRC). As will be discussed further below, the polymer layer 34 may also include nanocomposites of one or more of the above mentioned polymers.

The polymers cited above exhibit a relatively high glass transition temperature (Tg) (e.g. Tg greater than approximately 200 degrees C.) and are therefore stable at high temperatures. As such, capacitors fabricated with the above polymers may be operated at very high temperatures. For example, capacitors that include Ultem or Siltem may be able to operate at temperatures greater than 210 degrees C., which may be suitable for various high power electronic devices, such as the high-voltage switch-mode power convert shown in FIG. 2.

Furthermore, as mentioned above, the polymer layers 34 may include a nanocomposite of the abovementioned polymers. The nanocomposite polymer may include one of the polymers described above along with small high-permittivity nanoparticles, such as aluminum oxide (Al₂O₃) or silica. In the present discussion a nanoparticle is considered to be a particle with at least one dimension smaller than approximately 500 nanometers. The shapes of the nanoparticles may be spherical, flakes, fibers, or the like. Various high-permittivity nano-composites and methods of making the same can be found in U.S. Pat. No. 7,465,497 entitled “HIGH DIELECTRIC CONSTANT NANOCOMPOSITES, METHODS OF MANUFACTURE THEREOF, AND ARTICLES COMPRISING THE SAME,” by Qi Tan et al., the entirety of which is hereby incorporated by reference herein for all purposes.

Examples of materials that may be used to form the high permittivity nanoparticles include, but are not limited to: MgTiO₃, CaNb₂O₆, YTiTaO₆, MT-CT, CoNb₂O₆, CeO₂; ZnNb₂O₆; Ba(Mn_{1/3}Ta_{2/3})O₃; CaZrO₃; CMN; (SrCaBa)ZrO₃; Ba(Zn,Ta)O₃; SrZrO₃; Ba(Mg_{1/3}Nb_{2/3})O₃; Ca₂Nb₂O₇; ZnTiNb₂O₈; DyTiTaO₆; Nd₂Ti₂O₇; (Zr,Sn)TiO₄; Ba(Mn_{1/3}Nb_{2/3})O₃; Ba₂Ti₉O₂₀; Ba(Zn_{1/3}Nb_{2/3})O₃; ZrTiO₄; SnO₂—TiO₂; La₂Ti₂O₇; PrTiTaO₆; La₄Ba₂Ti₅O₁₈; CaTiO₃—Ca(Mg_{1/3}Nb_{2/3})O₃; CaTiO₃—Ca(Al_{1/2}Nb_{1/2})O₃; Sr₂Nb₂O₇; Sm_{9.33}Ba₄Ti₁₈O₅₄; (Li_{1/2}Nd_{1/2})TiO₃; BaO(La₂O₃Sm₂O₃)—4TiO₂; BaNd₂Ti₅Bi_{0.4}O_{14.75}; BaO—PbO—Nd₂O₃—TiO₂; BaNd₂Ti₅Bi_{0.4}O_{14.75}; TiO₂; SrSnO₃; CaTiO₃; SrTiO₃; Ag(Nb,Ta)O₃—CuO. In addition, nonlinear, high-permittivity nanoparticles may also be formed using: Pb(ZrₓTi₁₋ₓ)O₃; (BaₓSr₁₋ₓ)TiO₃; Pb₁₋ₓLaₓ(Zr_{y}Ti_{1-y})_{1-x/4}O₃; NaNbO₃; Pb₁₋ₓLaₓ(Zr_{y}Sn_{z}Ti_{1-y-z})_{1-x/4}O₃; wherein x, y, and z are amounts of up to about one and are independent of each other. By including high permittivity nanoparticles in the polymer layer, the capacitance of the MLP capacitor 30 may be greatly increased and the MLP capacitor 30 may also exhibit higher breakdown strength and increased thermal conductivity.

Furthermore, the stacked configuration of the capacitors provides additional benefits over traditional wound capacitors. The stacked configuration provides reduced ESR, reduced ESL, higher resonant frequency, lower dissipation factor, and higher current handling compared to comparable wound capacitors. Stacked capacitors in accordance with embodiments are also more dimensionally stable and more volumetrically efficient compared to wound capacitors. The benefits described above make the MLP capacitor 30 described herein well suited for high-voltage, high-frequency applications such as the power converting system of FIG. 2. Additionally, the stacked capacitor configuration makes the capacitor 30 more conducive to efficient mass-production compared to wound capacitors.

Moreover, it has been discovered that the polymer cyanoethyl cellulose provides a combination of thermal and electrical properties that makes it well suited for high temperature, high capacitance applications, such as POP devices 10. In particular, it has been discovered that high permittivity particles, such as those described above, provide a much greater increase in overall permittivity when the permittivity of the base polymer itself is also high, e.g. relative permittivity greater than ten. The polymer cyanoethyl cellulose exhibits thermal stability at high temperatures and a high relative permittivity. Thus, in some embodiments of the MLP capacitor 30, the polymer layer 34 includes a nanocomposite polymer with cyanoethyl cellulose for the base polymer. The cyanoethyl cellulose base polymer may operate at temperatures of about 270 degrees C. enabling it to withstand the high temperatures encountered during the soldering process. The relative permittivity of cyanoethyl cellulose is approximately 16, which enables the nanocomposite of cyanoethyl cellulose to achieve relative permittivity up to approximately 150, depending on the amount of nano-particles in the base polymer. Furthermore, the high permittivity of the polymer layers 54 increases the breakdown voltage above 10 Volts. Using cyanoethyl cellulose for the polymer layer 54, various compact, high-capacitance, high-temperature capacitors may be fabricated. Several exemplary embodiments of MLP capacitors 30 are described below.

In some embodiments, the thickness 40 of the polymer layers 34 may be approximately 50 nanometers and the composition of the polymer layer 34 may be unfilled (i.e., without nano-particles) cyanoethyl cellulose. In such embodiments, a capacitance density of 40 nanofarads or greater per square millimeter may be achieved with only 15 layers (i.e., 15 metal layers 56 and 15 polymer layers 54). As such, the thickness 74 of the MLP capacitor 30 may be approximately 800 to 1200 nanometers depending on the thickness 58 of the metal layers 56. In some embodiments, the thickness 74 of the unfilled cyanoethyl cellulose-based MLP capacitor 30 may be approximately 300 microns and may include approximately 3700 to 5400 layers. The capacitance density for such a capacitor may range from 10 to 14 microfarads, while still being small enough to fit within the approximately 300 micron thickness window available on the POP device 10.

In other embodiments, the thickness 40 of the polymer layers 34 may be approximately 1000 nanometers and the polymer layer 34 may include a cyanoethyl cellulose nano-composite. In such embodiments, a capacitance density of 40 nanofarads or greater per square millimeter may be achieved with only 5 layers (i.e., 5 metal layers 56 and 5 polymer layers 54.) As such, the thickness 74 of the MLP capacitor 30 may be approximately 5000 to 5200 nanometers depending on the thickness 58 of the metal layers 56. In some embodiments, the thickness 74 of the cyanoethyl cellulose nano-composite MLP capacitor 30 may be approximately 300 microns and may include approximately 290 to 300 layers. The capacitance density for such a capacitor may range from 2.3 to 2.4 microfarads, while still being small enough to fit within the approximately 300 micron thickness window (see, e.g., FIG. 1, height 26) available on the POP device 10. Additionally, the reduced number of layers used to achieve a particular capacitance makes the cyanoethyl cellulose nano-composite MLP capacitor 30 easier to fabricate in certain embodiments.

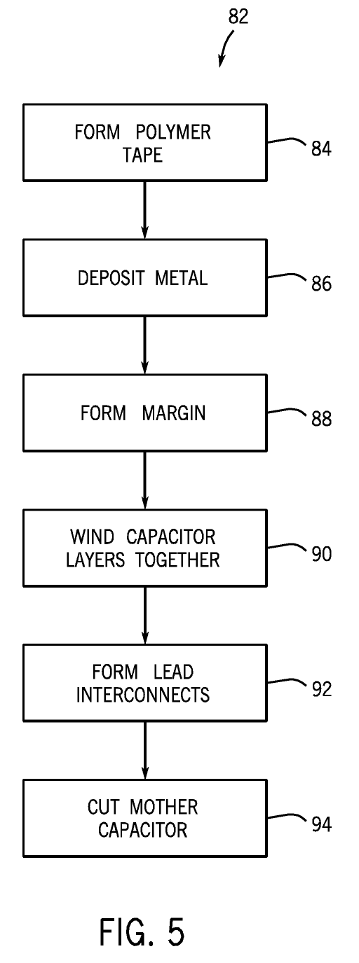

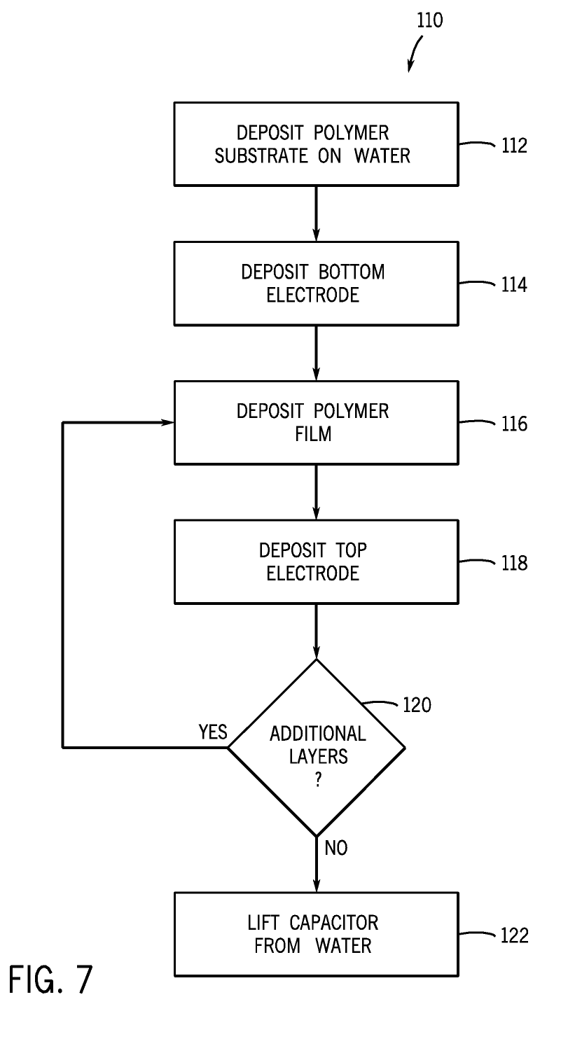

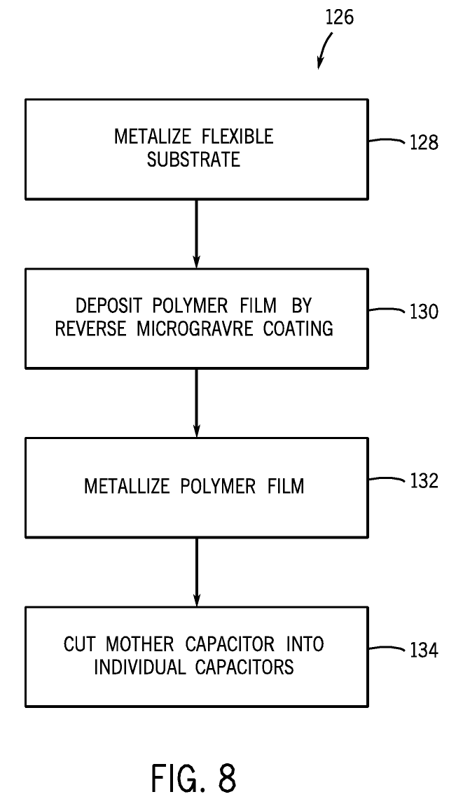

Various methods are possible for fabricating the stacked MLP capacitors 30 described above. For example, FIGS. 5 and 6 describe a method wherein a polymer film may be formed and metallized, and the metallized polymer film may then be rolled onto a large diameter wheel and segmented to form discrete, stacked capacitors. For another example, FIG. 7 describes a method of fabricating MLP capacitors 30 by depositing the polymer layers 54 and the metal layers 56 onto a silicon wafer. For yet another example, FIG. 8 describes a method of fabricating an MLP capacitor 30 using a reverse microgravure coating.

FIG. 5 is a flow chart illustrating an embodiment of a process 82 for fabricating a discrete MLP capacitor 30. FIG. 6 is a partial perspective view of a system used in some or all of the steps discussed in FIG. 5, therefore reference may be made to FIG. 6 during the description of process 82. Turning to FIG. 5, process 82 starts with step 84, wherein a polymer film is formed. As discussed above the polymer may include Ultem®, Extem®, Siltem®, another PEI-based polymer, cyanoethyl cellulose, or a nano-composite of one of the above. The polymer film may be melt extruded to a thickness of approximately 3 to 15 microns or solvent cast to a thickness of approximately 0.1 to 25 microns.

Next, at step 84, the polymer film is metallized. The metallizing at step 84 forms the metal layer 56 that will eventually be the electrodes of the MLP capacitor 30. Step 84 may include a process of vapor deposition, sputtering, or electrochemical deposition of metal onto the polymer film. Metals that may be deposited on the polymer film may include aluminum, copper, silver, gold, or alloys thereof, for example. The metal layer 56 resulting from the metallizing process may be 5 to 30 nanometers thick.

Next, at step 88, the insulative gap 66 is formed in the metal layer 56. The insulative gap 66 may be formed in a continuous line along one edge of the polymer film as dimensionally described above in relation to FIG. 3. In some embodiments, the insulative gap 66 may be formed by laser ablation. At the end of step 88, the metallized polymer films 94 shown in FIG. 6 are substantially complete.

At step 90, two of the polymer films 94 are wound together to form the electrode stack 52. Turning briefly to FIG. 6, a system of winding the two metallized polymer films is shown. First, two polymer films 94 are aligned as described above in relation to FIG. 3. Specifically, the two polymer films 94 are aligned with an offset 64 as shown in FIG. 3. Additionally, as shown in FIGS. 3 and 6, the insulative gaps 66 are positioned on opposite sides of the polymer film 94. The two polymer films 94 may then be wound together onto a rotating drum 96, as indicated by the arrow 100, to form a mother capacitor 102.

At step 92, after the mother capacitor 102 is formed, the lead terminations 62 may be deposited on the mother capacitor. As stated above, the lead terminations may include metals such as aluminum, tin, copper, etc., and may be vapor deposited on the sides of the electrode stack 52. The vapor deposition process may be physical vapor deposition process, such as sputtering, or a chemical vapor deposition process.

At step 92, the mother capacitor 102 is cut into individual, substantially rectangular MLP capacitors 30 as indicated in FIG. 6, by the arrow 104. Cutting the mother capacitor 102 may be accomplished by a saw 106, laser, or any other known cutting method. The dotted cutting line 106 indicates the line along which the mother capacitor 102 will be cut. In some embodiments, a metal-free margin 108 may be formed on either side of the cutting line 106. The metal-free margin 108 prevents the electrode layers from short circuiting as a result of the cutting process. The metal-free margin 108 may be formed by laser ablation or chemical etching. After cutting and separating the individual MLP capacitor 30 from the mother capacitor 102, the insulative terminations 80 may be added to the MLP capacitor 30. The MLP capacitor 30 is then ready to be coupled to a circuit such as the POP device 10 of FIG. 1 or the power converter system 36 of FIG. 2. In some embodiments, the MLP capacitor 30 may undergo further processing to encase the capacitor in an outer package to provide increased durability.

FIG. 7 is a flow chart illustrating an embodiment of a process 110 for fabricating a stacked MLP capacitor 30 on a silicon wafer. Those of ordinary skill in the art will recognize that some of the steps described below will include various methods of patterning the polymer layers and metal layers to fit the desired footprint of the capacitor(s). It will be understood, for example, that the formation of a metal or polymer layer may involve the use of photolithography or lift-off techniques wherein a coating of photoresist is deposited over the top surface of the semiconductor substrate 12 and exposed to a pattern of light that defines the desired structures.

In some embodiments, the method 110 may begin at step 112, wherein a polymer substrate is deposited on a silicon wafer. The silicon wafer may serve as a surface on which the capacitor 30 may be fabricated. As described below, the capacitor may eventually be removed from the silicon wafer, and the polymer substrate will then become the bottom layer of the capacitor 30. The purpose of the polymer substrate is to provide a flexible base that is compatible with the surface of the on which the capacitor will eventually be disposed, such as the POP device 10. In various embodiments, the polymer substrate may be polyethylene terephthalate (PET), polyimide (PI), or PEI, for example.

Next, at step 114, the bottom electrode of the electrode stack may be formed. To form the bottom electrode, a metal layer may be deposited on top of the polymer substrate. The metal layer may include any suitable metal, such as aluminum for example, and may be formed by any suitable method, such as chemical vapor deposition (CVD), physical vapor deposition (PVD), or sputtering, for example. After forming the metal layer, the metal layer may be patterned according to the desired footprint of the capacitor(s). In some embodiments, a shadow mask may be used to define the footprint of the metal layer(s). In this way, several individual metal layers may be patterned and deposited simultaneously.

At step 116, a polymer film is deposited over the bottom electrode. The purpose of this polymer film is to serve as the dielectric layer, as discussed above on relation to FIGS. 3 and 4. Accordingly, a solution of one of the polymers described above, such as cyanoethyl cellulose may be spin coated onto the surface of the substrate. Suitable solvents may include N-methylpyrrolidone or dimethylformamide, for example. Prior to depositing the polymer solution onto the substrate, the polymer solution may also be filtered and degassed. The viscosity of the polymer solution may be adjusted to affect the thickness of the resultant polymer layer. In some embodiments, the spin coating speed may range from 500 to 5000 revolutions per minute (RPM), and the spin coating times may range from 10 to 60 seconds. Furthermore, variations in the resulting thickness of the polymer layer may be reduced for high-viscosity polymer solutions by employing a spin coating time of 60 seconds or more. After spin coating the substrate with the polymer solution, the film may be dried. In some embodiments, the film may be dried at approximately 110 degrees Celsius for approximately 20 seconds and then dried at approximately 150 degrees Celsius for an additional approximately 15 minutes. In some embodiments, the polymer deposition may then be patterned according to the desired footprint of the capacitor(s).

At step 118, the top electrode of the electrode stack may be formed using substantially the same procedures described above in regard to step 114. At this time, a single layer capacitor has been formed, and method 110 may advance to step 120. From step 120, method 110 may return to step 116 if additional capacitor layers are to be deposited, in which case another polymer layer and electrode layer will be deposited according to the procedures of steps 116 and 118. If additional layers are not to be deposited, the method may advance to step 122

At step 122, the capacitors may be substantially complete and ready to be removed from the silicon wafer. At this time, if the polymer layers and the metal layers have been patterned after each deposition, several individual stacked capacitors may be formed on the wafer. In some embodiments, however, the polymer layers and metal layers may not have been patterned after each deposition, in which case, the layers deposited in steps 112 and 118 may be patterned together to form individual stacked capacitors. After patterning the capacitors, the capacitors may be removed from the wafer and disposed on a circuit such as a POP device 10.

Turning now to FIG. 8, a method of fabricating an MLP capacitor 30 using a reverse microgravure coating is shown, in accordance with embodiments. Method 126 starts at step 126 wherein a layer of metal is deposited on a flexible substrate such as polyester, for example. The flexible substrate provides a durable surface on which to deposit the MLP capacitor 30, and may be approximately 1.6 to 175 microns thick, in some embodiments. The metal layer may include any suitable metal, such as aluminum for example, and may be formed by any suitable method, such as chemical vapor deposition (CVD), physical vapor deposition (PVD), or sputtering. In certain embodiments, the metal layer may be vacuum evaporated onto the flexible substrate.

At step 130, a polymer film may be deposited over the metallized substrate by a reverse microgravure technique. According to the reverse microgravure technique, the flexible substrate is disposed adjacent to a roller containing a solution of the polymer to be deposited. The polymer solution may be a solution of one of the polymer discussed above in relation to FIGS. 3 and 4. The surface of the roller includes a mesh of engraved cells that hold the polymer solution. The substrate is then pulled past the roller as the roller rotates in the opposite direction until the desired length of the substrate is coated with the proper thickness of the polymer solution. The thickness of the resulting polymer layer may be controlled by the density of the mesh on the surface of the roller, the viscosity of the polymer solution, and the relative speed the substrate motion compared to the rotational rate of the roller. In some embodiments, the reverse microgravure coating may be performed using a MiniLabo™ table-top coater available from MIRWEC Film Inc. The coated substrate may then be baked to dry the polymer solution.

Next, at step 134, a metal layer may be deposited over the coated substrate, as described above in step 128 to form the top electrode. In some embodiments, steps 128 to 132 may be repeated to provide additional capacitor layers. In other embodiments, however, a single capacitor layer may be formed. After the desired number of capacitor layers have been formed, method 126 advances to step 134 wherein the mother capacitor may be cut into smaller capacitors, which may then be disposed on a circuit such as the POP device 10.

The aforementioned embodiments present clear advantages over existing film capacitors and methods for making such capacitors. The higher glass transition temperature of polyetherimide films such as the commercially available Ultem®, Siltem®, and Extem® films mentioned above enable a higher operating temperatures of the capacitors, while the stacked configuration provides improved electrical properties such as increased the resonant frequency, lower ESR, ESL, and dissipation loss. Together, the combination of improvements enable the MLP capacitors described herein to be used in higher-voltage, higher-frequency applications such as high-frequency, high-voltage, switched-mode power converters. Furthermore, MLP capacitors made with nano-particle filled cyanoethyl cellulose, provide very high capacitance density and can withstand temperatures encountered during soldering and other production processes, enabling their use in POP devices.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A capacitor comprising:
an electrode stack, including two or more electrodes disposed in a stacked configuration and a polymer dielectric disposed between each of the two or more electrodes;
wherein the polymer dielectric is comprised of polyetherimide or cyanoethyl cellulose.

2. The capacitor of claim 1, wherein the polymer dielectric is filled with high-permittivity nano-particles.

3. The capacitor of claim 1, wherein the polymer dielectric comprises a polyetherimide-siloxane composite.

4. The capacitor of claim 1, wherein the electrode stack is comprised of several layers of a metallized polymer film.

5. The capacitor of claim 1, comprising a first lead termination disposed on a first side of the electrode stack and a second lead termination disposed on a second side of the electrode stack, wherein the electrodes of the electrode stack are alternatingly coupled to either the first lead termination or the second lead termination.

6. The capacitor of claim 1, wherein the two or more electrodes are alternatingly shifted to the left and right sides of the electrode stack, and wherein the left-shifted electrodes are coupled to the first lead termination and the right-shifted electrodes are coupled to the second lead termination.

7. A power converting system, comprising:
a power converter configured to receive DC power from a DC input bus and output a voltage to an output bus for powering a load; and
one or more capacitors comprising an electrode stack that includes two or more electrodes disposed in a stacked configuration and a polymer dielectric disposed between each of the two or more electrodes;
wherein the polymer dielectric includes of polyetherimide and/or cyanoethyl cellulose.

8. The power converting system of claim 7, wherein the power converter is a DC to DC power converter configured to provide a DC output voltage to a load.

9. The power converting system of claim 7, wherein the power converter is a DC to AC power converter configured to provide an AC output voltage waveform to a load.

10. The power converter of claim 7, wherein the polymer dielectric is filled with high-permittivity nano-particles.

11. The capacitor of claim 7, wherein the polymer dielectric comprises a polyetherimide-siloxane composite.

12. An electronic device, comprising:
a first set of circuit components disposed on a bottom substrate configured to be soldered to a circuit board and provide electrical couplings between the bottom substrate and the circuit board;
a second set of circuit components disposed on a top substrate configured to be soldered to the bottom substrate and provide electrical couplings between the top substrate and the bottom substrate; and
one or more capacitors disposed on the bottom substrate and/or the top substrate adjacent to the first and/or second set of circuit components;
wherein the capacitors are disposed on the top and/or bottom substrate before the top and bottom substrates are soldered.

13. The electronic device of claim 12, wherein the capacitors include a dielectric layer comprising cyanoethyl cellulose.

14. The electronic device of claim 13, wherein the dielectric layer is comprised of high-permittivity nano-particles.

15. The electronic device of claim 12, wherein the capacitance density of at least one of the capacitors is greater than approximately 40 to 50 nanofarads per square millimeter.

16. A method of fabricating a capacitor, comprising:
forming at least one polymer film;
depositing a metal layer over the at least one polymer film;
winding the at least one polymer film onto a drum to form an electrode stack comprising at least two layers of the polymer film; and
cutting the electrode stack into several parallel-plate capacitors;
wherein the polymer film includes polyetherimide and/or cyanoethyl cellulose.

17. The method of claim 16, wherein winding the at least one polymer film onto a drum comprises winding two polymer films together, and wherein the two polymer films are offset laterally to form an overlapping region on both sides of the electrode stack.

18. The method of claim 16, comprising depositing metal lead terminations on the sides of the electrode stack, the metal leads configured to electrically couple the metal layers to a circuit.

19. The method of claim 18, comprising forming an insulative gap on opposite sides of the two polymer films, the insulative gap configured to electrically isolate the metal layers from one of the lead terminations.

21. The method of claim 16, wherein the polymer film is filled with high-permittivity nano-particles.

22. A method of fabricating a capacitor, comprising:
forming a polymer substrate on a silicon wafer;
forming a bottom electrode over the polymer substrate;
forming a polymer dielectric over the bottom electrode; and
forming a top electrode over the polymer dielectric;
wherein the wherein the polymer film includes polyetherimide and/or cyanoethyl cellulose.

23. The method of claim 22, wherein the polymer film comprises a nano-particle composite of cyanoethyl cellulose.

24. The method of claim 22, wherein the polymer film comprises a polyetherimide-siloxane composite
